(19) United States
(12) Patent Application Publication
(10) Pub. No.: US 2022/0397601 A1
(43) Pub. Date: Dec. 15, 2022

(54) TEST SYSTEM AND TEST METHOD TO A WAFER

(71) Applicant: NANYA TECHNOLOGY CORPORATION, New Taipei City (TW)

(72) Inventor: Ting-Wei YU, New Taipei City (TW)

(21) Appl. No.: 17/344,973

(22) Filed: Jun. 11, 2021

(51) Int. Cl. G01R 31/28

(52) U.S. Cl. CPC G01R 31/2889; G01R 31/2834

(57) ABSTRACT

A test method is disclosed. The test method includes the following operations: transmitting from a first controller a first command by a network to a test apparatus; the test apparatus being disconnecting from a prober in response to the first command received by a control interface in the test apparatus; controlling, by the control interface, at least one operation of the prober on a wafer held by the prober or a probe through a first control signal that is generated by the test apparatus to the prober and associated with the second command; and testing, by the prober and the test apparatus, the wafer and outputting a test data of the wafer.

### BACKGROUND

### Description of Related Art

In semiconductor industry, testers are utilized for analyzing characteristics and performance of integrated circuits on a wafer. When a test is performed to the wafer, a test engineer needs to change a position of the wafer in the clean room and goes back to the office for analyzing data, which wastes time.

### SUMMARY

One aspect of the present disclosure is to provide a test method, including the following operations: transmitting from a first controller a first command by a network to a test apparatus; the test apparatus being disconnecting from a prober in response to the first command received by a control interface in the test apparatus; controlling, by the control interface, at least one operation of the prober on a wafer held by the prober or a probe through a first control signal that is generated by the test apparatus to the prober and associated with a second command; and testing, by the prober and the test apparatus, the wafer and outputting a test data of the wafer.

Another aspect of the present disclosure is to provide a test system. The test system includes a prober, a test apparatus including a device interface to be coupled to the prober, and a first controller. The first controller is coupled to the test apparatus by a network. The first controller transmits a first command to the test apparatus to disconnect the device interface from the prober and activates a control interface in the test apparatus. When the control interface in the test apparatus is activated, the device interface is re-connected to the prober and the first controller transmits a second command, different from the first command, to the control interface in the test apparatus to control an operation of the prober.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a test system, in accordance with some embodiments of the present disclosure.

FIG. 2 is a schematic diagram of a test method, in accordance with some embodiments of the present disclosure.

FIG. 3 is a schematic diagram of a control interface in the test system in FIG. 1, in accordance with another embodiment of the present disclosure.

### DETAILED DESCRIPTION

The spirit of the present disclosure will be discussed in the following drawings and detailed description, and those of ordinary skill in the art will be able to change and modify the teachings of the present disclosure without departing from the spirit and scope of the present disclosure.

It should be understood that, in this document and the following claims, when an element is referred to as being “connected” or “coupled” to another element, it can be directly connected or coupled to another element, or there may be an intervening component. In contrast, when an element is referred to as being “directly connected” or “directly coupled” to another element, there is no intervening element. In addition, “electrically connected” or “connected” may also be used to indicate that two or more elements cooperate or interact with each other.

It should be understood that, in this document and the following claims, the terms “first” and “second” are to describe the various elements. However, these elements should not be limited by these terms. These terms are used to distinguish one element from another. For example, a first element may be termed a second element. Similarly, a second element may be termed a first element without departing from the spirit and scope of the embodiments.

It should be understood that, in this document and the following claims, the terms “include,” “comprise,” “having” and “has/have” are used in an open-ended fashion, and thus should be interpreted to mean “include, but not limited to.”

It should be understood that, in this document and the following claims, the term “and/or” includes any and all combinations of one or more of the associated listed items.

It should be understood that, in this document and the following claims, Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

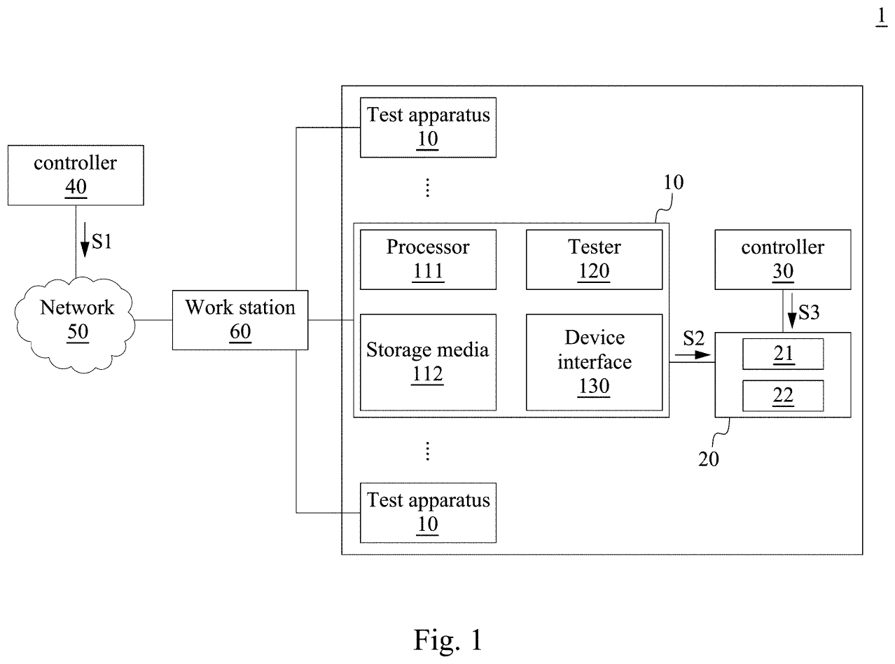

Reference is now made to FIG. 1. FIG. 1 is a schematic diagram of a test system 1, in accordance with some embodiments of the present disclosure. For illustration, the test system 1 includes multiple test apparatuses 10. Each test apparatus is coupled to a prober 20, and each prober 20 is coupled to a controller 30. The test system 1 further includes a controller 40, a network 50, and a work station 60. The controller 40 is connected to the work station 60 through the network 50. In some embodiments, the work station 60 is connected to multiple test apparatuses 10. In various embodiments, only one test apparatus is connected to the work station 60.

In some embodiments, the test apparatus 10 is configured as automatic test equipment (ATE) for testing semiconductor devices on a wafer 21 held by the prober 20. The semiconductor devices are created using a fabrication process, which includes any suitable manufacturing process for creating the semiconductor devices. The test apparatus 10 includes a processor 111 along with a storage media 112 as a computing system, a tester 120, and a device interface 130.

Specifically, the processor 111 comprises any suitable processor, such as a conventional central process unit (CPU, microcontroller (MCU), general processor circuit, operating in conjunction with any suitable operating system, such as Windows XP, Unix, or Linux. Similarly, the storage media 112 comprises any appropriate memory accessible to the processor 111, such as a random access memory (RAM) or other suitable storage system, for storing data. In particular, the storage media 112 of the present system includes a fast access memory for storing and receiving information and is suitably configured with sufficient capacity to facilitate the operation of the processor 111.

The tester 120 includes any test equipment that tests the wafer 21 and generates output test data acquired in testing, and includes multiple machines or other sources of data. In some embodiments, the tester 120 includes a conventional automatic tester, and suitably operates in conjunction with other equipment for facilitating the testing. The tester 120 is selected and configured according to the particular wafer 21 to be tested and/or any other appropriate criteria.

The tester 120 operates in conjunction with the processor 111 and the storage media 112 to, for example, program the tester 120, load and/or execute the test program, collect data, provide instructions to the tester 120, analyze test data, control tester parameters, and the like. In some embodiments, the storage media 112 includes capacity for storing output results received from the tester 120 and facilitating analysis of the output test data. The storage media 112 is configured for fast storage and retrieval of test data for analysis. In various embodiments, the storage media 112 is configured to store the elements of a dynamic datalog, suitably comprising a set of information selected by the test system 1 and/or the operator according to selected criteria and analyses based on the test results. For example, the storage media 112 stores a component identifier for the wafer 21, such as x-y coordinates corresponding to a position of the tested wafer 21. Furthermore, the processor 111 receives tester data from the tester 120 and performs various data analysis functions independently of the tester 120.

The device interface 130, like a conventional device interface board is coupled to the prober 20 to provide an interface between the tester 120 and the prober 20. In some embodiments, the device interface 130 includes general purpose interface bus (GPIB).

For illustration, the prober 20 includes a probe card 22 for testing the wafer 21. In some embodiments, the probe card 22 is configured to provide an electrical path between the test apparatus 10 and pads on an integrated circuit(s) of the wafer 21. The probe card 22 has electrical contact points (e.g., probe (tips), not shown) that match the size and density of the electrical pads the integrated circuit and conductive patterns that provide fan-out of electrical signals from these high density probes to the lower density connectors on the much larger printed circuit boards that interface to the test apparatus 10. In some embodiments, the probe card 22 is held in place on the prober 20, which moves the wafer 21 into position to make an electrical connection between the pads of the integrated circuit and the probe on the probe card 22.

The controllers 30 and 40 include separate computers, such as personal computers or processors to execute computer programs for controlling operations of the prober 20. In some embodiments, the controller 30 is directly coupled to the prober 20 to exchange signals while the controller 40 controls the operations of the prober 20 through transmitting commands by the network 50 to the test apparatus 10 and further transmitting, by the test apparatus 10, control signals to the prober 20.

The configurations of FIG. 1 are given for illustrative purposes. Various implements are within the contemplated scope of the present disclosure. For example, in some embodiments, the test apparatus 10 may include or be connected to other components, equipment, software, and the like to facilitate testing of the wafer 21 according to the particular configuration, application, environment of the test apparatus 10, or other relevant factors. For example, in some embodiments, the test apparatus 10 is connected to an appropriate communication medium, such as a local area network, intranet, or global network like the internet, to transmit information to other systems, such as a remote server for analyzing.

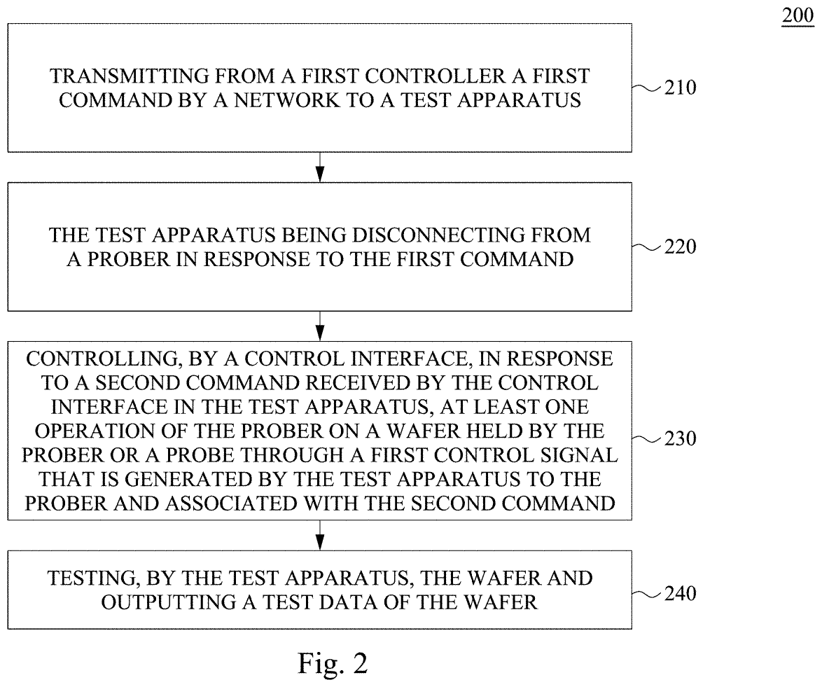

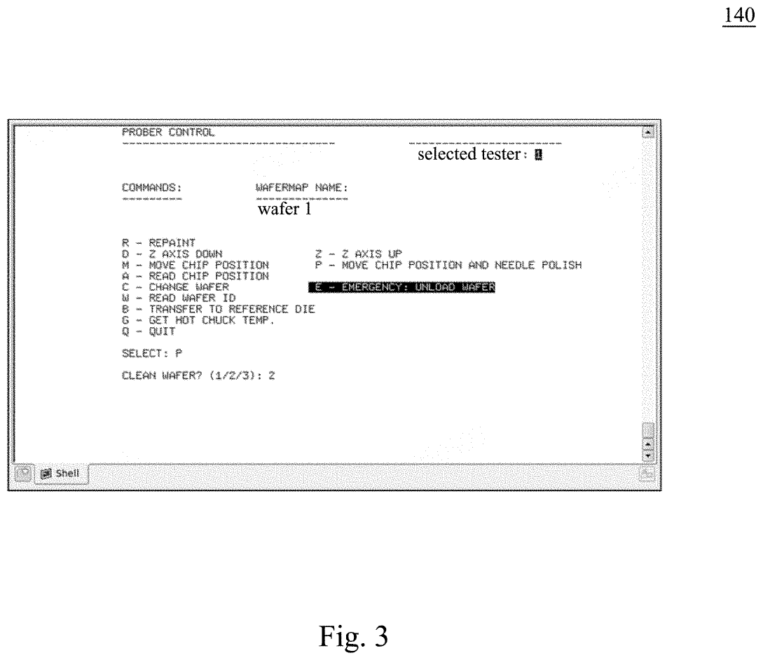

Reference is now made to FIG. 2. FIG. 2 is a schematic diagram of a test method 200 performed by the test system 1 in FIG. 1, in accordance with some embodiments of the present disclosure. It is understood that additional operations can be provided before, during, and after the processes shown by FIG. 2, and some of the operations described below can be replaced or eliminated, for additional embodiments of the test method 200. The test method 200 includes operations 210-240 that are described below with reference to FIGS. 1 and 3.

In operation 210, as shown in FIG. 1, the controller 40 transmits a first command to the test apparatus 10. In some embodiments, the first command includes instruction of switching the test apparatus 10 to a manual test mode that is controlled by the controller 40. The first command as codes is transmitted by a signal S1 to the work station 60 through the network 50, and is decoded by the processor 111.

In some embodiments, the first command includes instructions of selecting one of the test apparatuses 10. Accordingly, the controller 40 is connected and configured to control the selected test apparatus 10 through the work station 60 via the network 50, and further configured to active a control interface 140 (as shown in FIG. 3) in the selected test apparatus 10 to control the prober 20 coupled to the selected test apparatus 10. In some embodiments, the control interface 140 is programmable and performed by executing codes stored in the storage media 112 by the processor 111. In various embodiments, the control interface 140 is displayed in a display device (not shown) connected with the controller 40. Alternatively stated, a test engineer can input instruction remotely to control the test apparatus 10 when the controller 40 and the test apparatus 10 are at different localities. The detailed operation of the control interface 140 will be discussed in the following paragraphs.

In some embodiments, before the controller 40 transmits the first command to the test apparatus 10, the prober 20 is controlled by the test apparatus 10 to perform an auto test operation on the wafer 21 in response to the control signal S2 that is generated by the test apparatus 10 and transmitted through the device interface 130. The auto test operation includes operations of testing the whole wafer according to some test patterns for electrical characteristics of the integrated circuit(s) on the wafer. In some embodiments, the auto test operation is performed automatically by the test apparatus 10 in conjunction of the prober 20 in batch manufacturing process of fab.

In various embodiments, before the controller 40 transmits the first command to the test apparatus 10, the controller 30 controls the prober 20. When the controller 30 is disable, for example, crashed, the control interface 140 is activated in response to the first command including instructions of switching the test apparatus 10 to the manual test mode that is controlled by the controller 40, as illustrated in operation 210. By contrast, in some approaches of the prober 20 not being controlled by the controller 40, when the controller 30 is crashed, the prober 20 is idle while the controller 30 reboots, which reduces the productivity of entire test system 1. With the configurations of the present disclosure, although the controller 30 is disable to control the prober 20, prober 20 is available to perform testing while being controller by the controller 40. For example, in some embodiments, the prober 20 is controlled by the control interface 140, in response to the first command sent by the controller 40, in the test apparatus 10 to change a touchdown position on the wafer 21 in the prober 20. Accordingly, higher flexibility and productivity are provided by the present disclosure to the test system 1, compared with some approaches.

Following operation 210, in operation 220, the test apparatus 10 is disconnected from the prober 20 in response to the first command. Specifically, the operation of the test apparatus 10 being connecting includes operation of disconnecting the device interface 130 from the prober 20. Alternatively stated, the prober 20 terminals the previous operation, such like the auto test operation mentioned above, and no control signal is transmitted to the prober 20 from the test apparatus 10 through the device interface 130.

In some embodiments, the test method 200 further includes operations of activating, by the controller 40, the control interface 140 (shown in FIG. 3) in the test apparatus 10 responsive to the first command including instruction of switching the test apparatus 10 to a manual test mode that is controlled by the controller 40. The details of the control interface 140 in the manual test mode will be discussed in the following paragraphs. In some embodiments, the control interface 140 is executed to generate instructions to the tester 120 in order to generate, by the tester 120, control signals to the prober 20.

In some embodiments, after the control interface 140 is activated, the test method 200 further includes operations of connecting the device interface 130 of the test apparatus 10 to the prober 20. Alternatively stated, the test apparatus 10 is able to transmit the control signal S2, according to the control interface, to the prober 20 for further operations.

In operation 230, the control interface 140 controls, in response to a second command received by the control interface 140 in the test apparatus 10, at least one operation of the prober 20 on the wafer 21 held by the prober 20 or a probe of the probe card 22 through a control signal S2. The control signal S2 is generated by the test apparatus 10 to the prober 20 and associated with the second command, as shown in FIG. 1.

In some embodiments, the second command is transmitted to the control interface 140 after the first command. In various embodiments, the second command is different from the first command. To explain in another way, the first command is configured to active the control interface 140 and the second command is configured to control the control interface 140 for an operation(s) of the test apparatus 10 and the prober 20.

For example, as shown the control interface 140 in FIG. 3, the second command includes instructions of an operation of acquiring a configuration data of the prober 20 or instructions of an operation of moving elements, such like the wafer 21 and the probe of the probe card 22, of the prober 20.

Reference is now made to FIG. 3. FIG. 3 is a schematic diagram of the control interface 140 in the test system 1 in FIG. 1, in accordance with another embodiment of the present disclosure. For illustration, as shown in FIG. 3, the control interface 140 includes a user interface. The user interface has a command list, a wafermap name indicating a name of a tested wafer, a number of a selected tester (for example, the tester 120 in FIG. 2), a first select row, and a second select row. In some embodiments, the first select row is configured to display the second command that is received from the controller 40 and associated with one of instructions in the command list. The second select row is configured to display a third command that is received from the controller 40, and the third command indicates an intensity of cleaning operation to the test wafer. For example, when the third command includes instruction of, for example, “1,” the test wafer is cleaned with the smallest intensity.

In some embodiments, when the second command includes instructions of, for example, “A,” “W,” and “G,” the control interface 140 is executed and the test apparatus 10 accordingly generates the control signal S2 to control the prober 20 to feedback configuration data of, for example, “chip position (a current position where the probe of the probe card is, referred to as a touchdown position),” “wafer ID,” and “hot chuck temperature (the temperature of a chuck (not shown), on which the wafer 21 is disposed, the prober 20)” to the test apparatus 10 through the device interface 130. For example, as shown in FIG. 3, in response to the second command including the instruction of “W”, “the wafer ID” that is “wafer 1” and corresponds to the first wafer under testing is transmitted to the test apparatus 10 from the prober 20.

In some embodiments, the configuration data are then stored in the storage media 112 in FIG. 1.

In some embodiments, the control interface 140 is further configured to display the configuration data as mention above in a result page (not shown). For example, as shown in FIG. 3, when the second command includes instructions of, for example, “A,” is shown in the first select row, a corresponding coordinate of the touchdown position is display in the result page.

Moreover, in some embodiments, when the second command includes instructions of, for instance, “D” and “Z”, the control interface 140 is executed and the test apparatus 10 accordingly generates the control signal S2 to control the chuck of the prober 20 to vertically move the wafer 21 in the z direction in order to press selected group of dies on the wafer 21 in contact with the probe in the probe card 22 and to disconnect the selected group of dies on the wafer 21 from the probe in the probe card 22 respectively, as shown in FIG. 3. In some embodiments, Each instance of contact between the wafer 21 and the probe in the probe card 22 is referred to herein as a touchdown or TD.

In some embodiments, when the second command includes instructions of, for instance, “M”, the control interface 140 is executed and the test apparatus 10 accordingly generates the control signal S2 to control the chuck of the prober 20 to horizontally move the wafer 21 in the x or y direction (on a plane of the prober 20) to a predestinated position for further testing. In some embodiments, the second command includes x and/or coordination of the predestinated position. In various embodiments, when the second command includes instructions of, for instance, “P”, in addition to changing the position of the wafer 21, polish operation to a probe tip (needle) of the probe in the probe card 22 is performed by the prober 20 to, for example, remove debris accumulated on the probe tip, which improves better contact between the probe in the probe card 22 and pad of the selected groups of dies on the wafer 21.

In some embodiments, when the second command includes instructions of, for instance, “C”, the control interface 140 is executed and the test apparatus 10 accordingly generates the control signal S2 to the prober 20 to change the wafer 21 and get another one from a lot of the wafers 21 for testing. In various embodiments, when the second command includes instructions of, for instance, “E”, the control interface 140 is executed and the test apparatus 10 accordingly generates the control signal S2 to the prober 20 to upload the wafer 21 for emergency checking. Alternatively stated, the testing of the wafer 21 terminates.

In some embodiments, when the second command includes instructions of, for instance, “R”, the control interface 140 is executed to replaint the user interface. For example, after receiving the second command including instructions of “R,” the control interface 140 flushes the result page and then displays the user interface. In some embodiments, because of the abnormal connection between the test apparatus 10 and the prober 20, the control interface 140 does not receive feedback from the prober 20 and is stuck at the result page. The controller 40 transmits the second command including instructions of “R,” to control the control interface to display the user interface for operation, instead of the test apparatus being idle.

In some embodiments, when the second command includes instructions of, for instance, “B”, the control interface 140 is executed and the test apparatus 10 accordingly generates the control signal S2 to the prober 20 to perform an auto test operation on the wafer 21, for example, a test(s) arranged in manufacturing process of the wafer 21 or any suitable test. In various embodiments, after receiving the instructions of “B”, firstly, the device interface 130 of the test apparatus 10 is disconnected from the prober 20. Then, the control interface 140 is executed to control the device interface 130 to be connected to the prober 20, and executes instructions, such like test pattern, stored in the storage media 112 for performing the auto test operation on the wafer 21.

In some embodiments, the second command includes instructions of a number, for instance, “2”, the control interface 140 is executed and the test apparatus 10 accordingly generates the control signal S2 to the prober 20 to clean the wafer 21 in a second level intensity. In various embodiments, the number indicates the intensity level of the clean operation.

The configurations of FIG. 3 are given for illustrative purposes. Various implements are within the contemplated scope of the present disclosure. For example, in some embodiments, the control interface 140 could perform additional functions based on actual practice of the present disclosure.

In operation 240, the wafer 21 is tested by the prober 20 and the test apparatus 10, and the test apparatus 10 outputs a test data of the wafer 21.

In some embodiments, after the wafer 21 is tested manually according to the second command, the controller 40 transmits a third command to the control interface 140, in which the third command includes instructions of (for example, “B” as mentioned above) switching the test apparatus 10 to perform the auto test operation on the wafer 21. Accordingly, the prober 20 conducts the auto test operation on the wafer. Alternatively stated, the controller 40 is configured to switch an operation mode of the probe3 20 and the test apparatus 10.

In some embodiments, the test apparatus 10, the prober 20, and the controller 30 are located in a clean room, and the controller 40 is located outside of the clean room. Accordingly, with the configuration of the present disclosure, a test engineer can control the test apparatus 10 and the prober 20 remotely without being in the clean room, which saves time of commuting between the clean room and an analyzing office.

Through the operations of the various embodiments above, the test system and the test method provided by the present disclosure provide flexibility and productivity in testing a wafer by utilizing a customized control interface, by a remote controller, to control the device interface connected to the prober.

While the disclosure has been described by way of example(s) and in terms of the preferred embodiment(s), it is to be understood that the disclosure is not limited thereto. Those skilled in the art may make various changes, substitutions, and alterations herein without departing from the spirit and scope of the present disclosure. In view of the foregoing, it is intended that the present invention cover modifications and variations of this invention provided they fall within the scope of the following claims.

What is claimed is:

1. A test method, comprising:
transmitting from a first controller a first command by a network to a test apparatus;
the test apparatus being disconnecting from a prober in response to the first command;
controlling, by a control interface, in response to a second command received by the control interface in the test apparatus, at least one operation of the prober on a wafer held by the prober or a probe through a first control signal that is generated by the test apparatus to the prober and associated with the second command; and
testing, by the prober and the test apparatus, the wafer and outputting a test data of the wafer.

2. The test method of claim 1, wherein the test apparatus being disconnecting comprises:
disconnecting a device interface of the test apparatus from the prober;
wherein the test method further comprises:
connecting the device interface of the test apparatus to the prober.

3. The test method of claim 1, wherein the second command includes instruction of an operation of acquiring a configuration data of the prober.

4. The test method of claim 1, wherein the second command indicates instruction of an operation of moving the wafer to a predestinated position.

5. The test method of claim 1, further comprising:
activating the control interface in response to the first command including instruction of switching the test apparatus to a manual test mode controlled by the first controller.

6. The test method of claim 5, wherein the second command indicates instruction of controlling, by the control interface, the prober to perform an auto test operation on the wafer.

7. The test method of claim 1, further comprising:
when a second controller configured to control the prober is disable, activating the control interface in response to the first command including instructions of switching the test apparatus to a manual test mode controlled by the first controller.

8. The test method of claim 1, further comprising:
before transmitting the first command from the first controller to the test apparatus, controlling, by the test apparatus, the prober to perform an auto test operation on the wafer in response to a second control signal that is generated by the test apparatus and transmitted through a device interface.

9. A test system, comprising:
a prober;
a test apparatus comprising a device interface to be coupled to the prober; and
a first controller connected to the test apparatus by a network, wherein the first controller is configured to transmit a first command to the test apparatus to disconnect the device interface from the prober and to activate a control interface in the test apparatus,
wherein when the control interface in the test apparatus is activated, the device interface is re-connected to the prober and the first controller is configured to transmit a second command, different from the first command, to the control interface in the test apparatus to control an operation of the prober.

10. The test system of claim 9, further comprising:
a second controller coupled to the prober and configured to control the operation of the prober, wherein when the second controller is disable, the prober is controlled by the control interface in the test apparatus to change a touchdown position on a wafer in the prober.

11. The test system of claim 10, wherein the prober, the test apparatus and the second controller are located in a clean room, and the first controller is located outside of the clean room.

12. The test system of claim 9, wherein the device interface includes a general purpose interface bus (GPIB).

13. The test system of claim 9, wherein the first controller is further configured to transmit a third command to the test apparatus to disconnect the device interface from the probe, and
the control interface in the test apparatus is further configured to connect the device interface to the probe in response to the third command to perform an auto test operation on a wafer.

14. The test system of claim 9, wherein the prober is configured to feedback a configuration data to the test apparatus in response to a control signal that is generated by the test apparatus and associated with the second command.

15. The test system of claim 9, further comprising:
a plurality of the test apparatuses and a plurality of the probers; and
a work station that is coupled to the plurality of the test apparatuses and connected to the first controller through the network,
wherein the first controller is configured to be connected to a selected one of the plurality of the test apparatuses and to activate the control interface in the selected one of the plurality of the test apparatuses to control one of the plurality of the probers coupled to the selected one of the plurality of the test apparatuses.
